(19) United States
(12) Patent Application Publication
(10) Pub. No.: US 2013/0176546 A1
(43) Pub. Date: Jul. 11, 2013

(54) Illumination optical unit with a movable filter element

(71) Applicants: Michael Layh, Altusried (DE); Damian Fiolka, Oberkochen (DE)

(72) Inventors: Michael Layh, Altusried (DE); Damian Fiolka, Oberkochen (DE)

(73) Assignee: Carl Zeiss SMT GmbH, Oberkochen (DE)

(21) Appl. No.: 13/784,027

(22) Filed: Mar. 4, 2013

Related U.S. Application Data
(63) Continuation of application No. PCT/EP2011/061631, filed on Jul. 8, 2011.

(30) Foreign Application Priority Data
Sep. 23, 2010 (DE) 102010041258.9

(51) Int. Cl. F21V 9/10; G03F 7/20

(52) U.S. Cl. CPC F21V 9/10; G03F 7/70191
USPC 355/71; 362/319; 362/277

(57) ABSTRACT

An illumination optical unit illuminates an object field using radiation with a first wavelength. The illumination optical unit includes a filter element for suppressing radiation with a second wavelength. The filter element includes at least one component with an obscuring action. As a result of the obscuring action, during operation of the illumination optical unit there is at least one region of reduced intensity of radiation with the first wavelength on a first optical element, arranged downstream of the filter element in the light direction, of the illumination optical unit. The filter element can assume a multiplicity of positions, which lead to different regions of reduced intensity. For each point on an optical used surface of the first optical element, there is at least one position such that the point does not lie in a region of reduced intensity.

### CROSS-REFERENCE TO RELATED APPLICATIONS

This application is a continuation of, and claims priority under 35 U.S.C. §120 to, International Patent Application Serial Number PCT/EP2011/061631, filed Jul. 8, 2011. International Patent Application Serial Number PCT/EP2011/061631 claims benefit under 35 U.S.C. §119 of German Patent Application No. 10 2010 041258.9, filed on Sep. 23, 2010. The entire disclosure of each of these patent applications is incorporated by reference in the present application.

### FIELD

The disclosure relates to an illumination optical unit for illuminating an object field using radiation with a first wavelength. The illumination optical unit includes a filter element for suppressing radiation with a second wavelength. The disclosure also relates to a method for operating a microlithography projection exposure apparatus which includes such an illumination optical unit.

### BACKGROUND

Microlithography projection exposure apparatuses serve for producing microstructured components by a photolithographic method. A structure-bearing mask, the so-called reticle, is illuminated with the aid of a light-source unit and an illumination optical unit and is imaged onto a photosensitive layer with the aid of a projection optical unit. The light-source unit makes available radiation which is guided into the illumination optical unit. The illumination optical unit serves for making available at the location of the structure-bearing mask a uniform illumination with a predetermined angle-dependent intensity distribution. For this purpose, various suitable optical elements are provided within the illumination optical unit. The structure-bearing mask illuminated in this way is imaged onto a photosensitive layer with the aid of the projection optical unit. The minimum structure width that can be imaged with the aid of such a projection optical unit is determined, among other things, by the wavelength of the utilized radiation. In general, the shorter the wavelength of the radiation is, the smaller the structures are which can be imaged with the aid of the projection optical unit. For this reason, it is advantageous to use radiation having the wavelength from 5 nm to 15 nm.

Microlithography projection exposure apparatuses are often operated as so-called scanners. This means that the reticle is moved through a slotted object field along a scan direction during a specific exposure duration, while the wafer is correspondingly moved in the image plane of the projection optical unit. The ratio of the speeds of wafer to reticle corresponds to the magnification of the projection optical unit between reticle and wafer, which is usually less than one.

Since the chemical alteration of the photosensitive layer only takes place to a sufficient extent after a specific radiation dose has been administered, it is desirable to ensure that all regions of the reticle which are intended to be illuminated receive the same radiation energy.

Non-uniformities in the distribution of the radiation energy in the object plane can lead to variations in the structure width because the position of the edges of structures to be exposed depends on whether or not the appropriate radiation energy for exposure was attained.

Since the scanning process results in an integration of the radiation energy along the scanning direction, the relevant variable is the scan-integrated dose, i.e. the integral:

$$D ( x ) = {\int }_{0}^{T} ρ ( x , y ( t ) , t ) d t .$$

The y-direction corresponds to the scanning direction, and the x-direction lies within the object plane and is perpendicular to the scanning direction. ρ(x,y,t) is the irradiance at a time t in the object plane. ρ(x,y,t) has units of

$$\frac{Joule}{{mm}^{2} \cdot s} ,$$

and so the scan-integrated dose D(x) has units of

$$\frac{Joule}{{mm}^{2 }} .$$

y(t) is the curve along which a point of the reticle is, as a result of the scanning process, moved through the illuminated object field during the period of time from 0 s to T. In particular, in the case of a scanning process with the constant scanning speed v_{scan}, y(t)=v_{scan}·t applies.
Light-source units are typically operated in pulsed fashion in lithography, and so the irradiance ρ(x,y,t) only differs from zero at a few times t₁, . . . , t_{N} within the period of time T. In this case, the scan-integrated dose can be represented by the following sum:

$$D ( x ) = {\sum }_{i = 1}^{N} {ɛ}_{i} ( x , y ( {t}_{i} ) )$$

where εᵢ (x,y(tᵢ)) is the illumination energy density which, at time tᵢ, acts on the point (x,y(tᵢ)) from the i-th pulse of light.

However, in order to use radiation with the wavelength from 5 nm to 15 nm, it is desirable to use luminous source plasma as a light source. By way of example, such a light-source unit can be a laser plasma source (LPP). In this source type, tightly restricted source plasma is created by virtue of a small material droplet being produced by a droplet generator and being moved to a predetermined location. There the material droplet is irradiated by a high-energy laser, and so the material changes into a plasma state and emits radiation in the 5 to 15 nm wavelength range. By way of example, an infrared laser with a wavelength of 10 μm is used as laser. Alternatively, the light-source unit can also be a discharge source, in which the source plasma is created with the aid of a discharge. In both cases, radiation with a second, unwanted wavelength also occurs in addition to the wanted radiation with a first wavelength in the range of 5 to 15 nm, which is emitted by the source plasma. This second radiation is, for example, radiation emitted by source plasma outside of the wanted range of 5 to −15 nm or, particularly if use is made of a laser plasma source, laser radiation which was reflected by the source plasma. As a result, the second wavelength typically lies in the infrared range of from 0.78 μm to 1000 μm, particularly in the range of from 3 to 50 μm. When the projection exposure apparatus is operated with a laser plasma source, the second wavelength particularly corresponds to the wavelength of the laser used to produce the source plasma. If use is made of a CO₂ laser, this is e.g. the wavelength of 10.6 μm. The radiation with the second wavelength cannot be used for imaging the structure-bearing mask because the wavelength is too long for imaging the mask structures in the nanometer range. The radiation with the second wavelength therefore only leads to unwanted background brightness in the image plane. Furthermore, the radiation with the second wavelength leads to heating of the optical elements in the illumination optical unit and the projection optical unit.

### SUMMARY

Filter elements used to suppress radiation at a second wavelength typically also affect radiation at a first wavelength. Thus, many such filter elements include at least one component with an obscuring action. As a result of the obscuring action, during operation of the illumination optical unit there is at least one region of reduced intensity of radiation with the first wavelength on a first optical element, arranged downstream of the filter element in the light direction, of the illumination optical unit. However, this leads to intensity variations in the radiation with the first wavelength at the location of the object field as a result of the utilized filter element (leads to a varying uniformity curve).

The disclosure provides an illumination optical unit with a filter element for suppressing radiation with a second wavelength while exhibiting a reduced effect on the intensity variations of radiation with a first wavelength.

The disclosure provides a filter element that can assume a plurality of positions, which lead to different regions of reduced intensity. There is at least one position for each point on an optical used surface of the first optical element such that the point does not lie in a region of reduced intensity. Hence, the position of the filter element can be changed during the scan duration in order to achieve a temporal change in the irradiance ρ(x,y,t). Since the dose D(x) is a time integral, this can bring about averaging (a more uniform dose in the x-direction).

This is desired, in particular, if the first optical element is a mirror with a multiplicity of first reflective facet elements, which are imaged on the object field by at least one second optical element, because intensity variations on the first optical element are transmitted particularly clearly onto the object field in this case.

Furthermore, such a filter element is desired, in particular, if the first wavelength lies in the range of from 5 to 15 nm, because radiation with a second wavelength is usually also generated simultaneously when generating such radiation. This second wavelength typically lies in the infrared range of 0.78 μm to 1000 μm, in particular in the range of 3 to 50 μm.

In one embodiment, the filter element is a periodic grating made of conductive material. The grating period is selected so that radiation with the second wavelength is absorbed or diffracted out of the beam path. The component with the obscuring action corresponds to the grating. Such gratings are known from U.S. Pat. No. 6,522,465 B2 and have a grating period that is typically shorter than the second wavelength (sub-lambda grating).

In an alternative embodiment, the filter element includes a film with a thickness of less than 500 nm, more particularly of less than 300 nm. Material and thickness of the film are selected so that the film absorbs a proportion of at least 90% of the radiation with the second wavelength and transmits a proportion of at least 70% (preferably of at least 80%, particularly preferably of at least 95%) of the radiation with the first wavelength. The advantage of this is that the filter element includes a smaller number of components with an obscuring action than in the embodiment with the periodic grating since it is possible to dispense with grating struts.

Additionally, the component with the obscuring action can include holding bodies for strengthening the mechanical stability of the filter element. It is particularly advantageous if the holding bodies as thermal conductors for cooling the filter element since the filter element heats up during operation as a result of the absorption of the radiation with the second wavelength and hence emits black body radiation, which, among other things, is directed so that it heats the optical elements. In particular, the holding bodies can as hollow struts, which are filled with a liquid for heat transport. This achieves particularly good thermal dissipation.

In a special development, the filter element can be shifted from the first position into the second position by being rotated about a central axis. Such a change in position can be realized particularly easily from a mechanical point of view and can be continuously maintained during the operation of the illumination optical unit.

Mechanically such an embodiment can be realized particularly easily if the filter element is connected to a shaft for rotating the filter element, wherein the shaft extends along the central axis.

In specific embodiments, the filter element includes a drive unit for rotating the filter element about the central axis. The drive unit engages on a circumference of the filter element. This makes it possible to arrange the drive unit at a position at which it does not shadow any radiation from the light-source unit.

In particular, the filter element can be designed so that paddles are arranged on the circumference of the filter element and the drive unit includes a gas actuator, which produces a gas flow directed at the paddles such that the gas pressure generates a mechanical drive force. This makes it possible to avoid vibrations being transmitted from a mechanical drive to the filter element. Furthermore, the filter element is not rigidly connected, and so it can vibrate freely and expand when heated. A further advantage of this is that constraining forces acting on the filter element are avoided or reduced.

An illumination system with an illumination optical unit described above has the advantages noted above with respect to the illumination optical unit.

In a special development, the illumination system includes an illumination optical unit and a light-source unit. The central axis, about which the filter element is rotated, intersects the filter element at an intersection point. The intersection point lies within a convex envelope of all regions on the filter element which are illuminated by the light-source unit with radiation with the first and the second wavelength. This can achieve a particularly compact design of the filter element because the axis of rotation lies in the middle of the light beam.

A microlithography projection exposure apparatus having an illumination system described above has the advantages noted with respect to the illumination system.

In one aspect, the disclosure provides a method for operating a microlithography projection exposure apparatus. The method includes moving the filter element from the first position to the second position within a first period of time, which is less than a second period of time during which a point on the structure-bearing mask is moved through the object field. Because the dose D(x) is a time integral of the irradiance ρ(x,y,t), this can achieve temporal averaging. This additional temporal averaging leads to smaller variations of D(x) as a function of x. This therefore results in better results of the lithographic process.

In one aspect, the disclosure provides a method for operating a microlithography projection exposure apparatus. The method includes rotating the filter element about the central axis with a speed of more than 5 revolutions (more particularly more than 10 revolutions) per second.

Rotating the filter element with such a rotational speed ensures that the filter element heats up uniformly and that there is a sufficient temporal averaging of the scan-integrated irradiance D(x).

### BRIEF DESCRIPTION OF THE DRAWINGS

The disclosure is explained in more detail on the basis of the drawings, in which:

FIG. 1a shows a projection exposure apparatus according to the disclosure with an illumination optical unit;

FIG. 1b shows a plan view of the first optical element of the illumination optical unit;

FIG. 1c shows a plan view of the second optical element of the illumination optical unit;

FIG. 2 shows a projection exposure apparatus according to the disclosure with an alternative illumination optical unit;

FIG. 3a shows a first embodiment of the filter element according to the disclosure;

FIG. 3b shows a second embodiment of the filter element according to the disclosure;

FIG. 3c shows a third embodiment of the filter element according to the disclosure;

FIG. 4a shows a plan view of the first optical element including the regions of reduced intensity which emerge as a result of the filter element as per the first embodiment according to FIG. 3a;

FIG. 4b shows a similar illustration to FIG. 4a, wherein the regions of reduced intensity differ because the filter element was shifted into another position;

FIGS. 5a, 5b and 5c show a special mechanical embodiment of the filter element according to the disclosure. Here, FIG. 5a shows a plan view of the filter element, FIG. 5b shows a section through the filter element, with the central axis lying in the sectional plane, and FIG. 5c shows a section through the filter element, with the sectional plane lying perpendicular to the central axis;

FIG. 6a shows a section through the filter element according to the disclosure in an alternative mechanical embodiment, with the central axis lying in the sectional plane, and FIG. 6b shows the associated section in which the central axis is perpendicular to the sectional plane;

FIG. 7a shows a plan view of the filter element according to the disclosure in an alternative mechanical embodiment and FIG. 7b shows a section through the filter element in this embodiment, with the central axis lying in the sectional plane;

FIG. 7c shows an embodiment with a drive unit which engages on the circumference; and

FIG. 8 shows the filter element according to FIG. 5a within a beam path.

### DETAILED DESCRIPTION

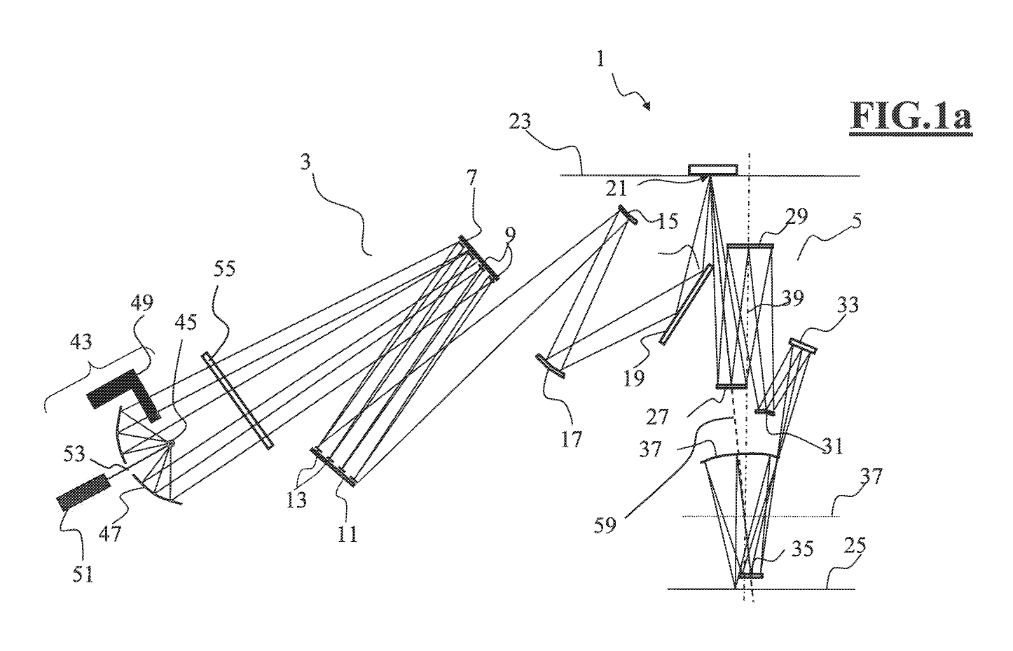

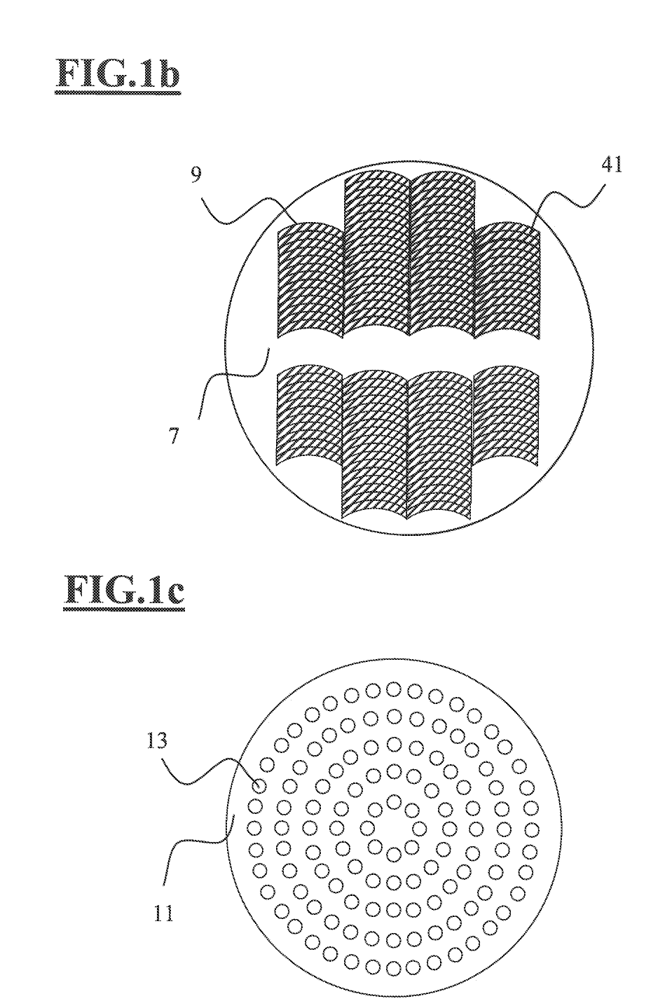

The reference signs have been selected in such a way that objects which are illustrated in FIG. 1 have been provided with single-digit or two-digit numbers. The objects illustrated in the further figures have reference signs consisting of three or more digits, wherein the last two digits specify the object and the preceding digit specifies the number of the figure in which the object is displayed. As a result, the reference signs of the same objects which are illustrated in a number of figures correspond in the last two digits. The description of these objects is possibly found in text relating to a preceding figure.

FIG. 1a shows an embodiment of a projection exposure apparatus 1 according to the disclosure with an illumination optical unit 3 and a projection optical unit 5. Here, the illumination optical unit 3 includes a first optical element 7 with a plurality of reflective first facet elements 9, and a second optical element 11 with a plurality of second reflective facet elements 13. Arranged in the light path downstream of the second optical element 11 are a first telescope mirror 15 and a second telescope mirror 17, which are both operated with normal incidence, that is to say the radiation impinges on both mirrors at an angle of incidence of between 0° and 45°. Here, the angle of incidence is understood to be the angle between incident radiation and the normal of the reflective optical surface. A deflection mirror 19 is arranged downstream in the beam path and guides the radiation impinging thereon onto the object field 21 in the object plane 23. The deflection mirror 19 is operated with grazing incidence, that is to say the radiation impinges on the mirror at an angle of incidence of between 45° and 90°. A reflective structure-bearing mask is arranged at the location of the object field 21 and imaged into the image plane 25 with the aid of the projection optical unit 5. The projection optical unit 5 includes six mirrors 27, 29, 31, 33, 35 and 37. All six mirrors of the projection optical unit 5 each have a reflective optical surface extending along a surface that is rotationally symmetric about the optical axis 39.

FIG. 1b shows a plan view of the first optical element 7, which includes a plurality of first reflective facet elements 9. Each of the first reflective facet elements 9 has a reflective surface for reflecting the impinging radiation. The totality of all reflective surfaces of the first reflective facet elements 9 is referred to as optical used surface 41 of the first optical element 7. In FIG. 1b, the optical used surface 41 has been illustrated by shading.

FIG. 1c shows a corresponding plan view of the second optical element 11 with a plurality of second reflective facet elements 13.

The projection exposure apparatus according to FIG. 1a furthermore includes a light-source unit 43, which guides radiation onto the first optical element 7. Here, the light-source unit 43 includes source plasma 45 and a collector mirror 47. The light-source unit 43 can be configured in different embodiments. A laser plasma source (LPP) is illustrated. Tightly restricted source plasma 45 is created in this source type, in which a small material droplet is produced using a droplet generator 49 and moved to a predetermined location. There, the material droplet is irradiated by a high-energy laser 51, and so the material changes into a plasma state and emits radiation in the 5 to 15 nm wavelength range. Here, the laser 51 can be arranged in such a way that the laser radiation falls through an opening 53 in the collector mirror before it impinges on the material droplet. By way of example, an infrared laser with a wavelength of 10 μm is used as laser 51. Alternatively, the light-source unit 43 can also be a discharge source, in which the source plasma 45 is created with the aid of a discharge. In both cases, radiation with a second, unwanted wavelength also occurs in addition to the wanted radiation with a first wavelength in the range of from 5 to 15 nm, emitted by the source plasma. By way of example, this unwanted radiation is radiation emitted by source plasma outside of the wanted range of from 5 to 15 nm or, particularly if use is made of a laser plasma source, laser radiation which was reflected by the source plasma. As a result, the second wavelength typically lies in the infrared range of from 0.78 μm to 1000 μm, particularly in the range from 3 μm to −50 μm. When operating the projection exposure apparatus with a laser plasma source, the second wavelength in particular corresponds to the wavelength of the laser 51 used to create the source plasma 45. If use is made of a CO₂ laser, this is, for example, the 10.6 μm wavelength. The radiation with the second wavelength cannot be used for imaging the structure-bearing mask at the location of the object field 21 since the wavelength is too long for imaging the mask structures in the nanometer range. The radiation with the second wavelength therefore leads to unwanted background brightness in the image plane 25, particularly in the wavelength range from 100 nm to 300 nm (DUV). The radiation with the second wavelength, particularly in the infrared range, furthermore leads to heating up of the optical elements in the illumination optical unit and the projection optical unit. It is for these two reasons that, according to the disclosure, provision is made for a filter element 55 for suppressing radiation with the second wavelength. The filter element 55 is arranged in the beam path between the light-source unit 43 and the first reflective optical element 7 of the illumination optical unit 3. As a result of this, the radiation with the second wavelength is suppressed as early as possible. Alternatively, the filter element 55 can also be arranged at other positions in the beam path. By way of example, the filter element can be a periodic grating made of conductive material, wherein the grating period is selected in such a way that the radiation with the second wavelength is absorbed. By way of example, such gratings are known from U.S. Pat. No. 6,522,465, the content of which is incorporated into this application in its entirety. Alternatively, or in addition thereto, the filter element can include a film with a thickness of less than 500 nm, wherein material and thickness of the film are embodied in such a way that the film absorbs a proportion of at least 90% of the radiation with the second wavelength and transmits a proportion of 70% of the radiation with the first wavelength. The radiation now spectrally adjusted in this fashion illuminates the first reflective optical element 7. The collector mirror 49 and the first reflective facet elements 9 have such an optical action that images of the source plasma 45 result at the locations of the second reflective facet elements 13 of the second optical element 11. To this end, on the one hand, the focal lengths of the collector mirror 49 and of the first facet elements 9 are selected in accordance with the spatial distances. By way of example, this is brought about by virtue of the reflective optical surfaces of the first reflective facet elements 9 being provided with suitable curvatures. On the other hand, the first reflective facet elements 9 have a reflective optical surface with a normal vector, the direction of which fixes the orientation of the reflective optical surface in space, wherein the normal vectors of the reflective surfaces of the first facet elements 9 are oriented in such a way that the radiation reflected by a first facet element 9 impinges on an associated second reflective facet element 13. The second reflective facet element 13 is arranged in a pupil plane of the illumination optical unit 3, which is imaged on the exit pupil plane with the aid of the mirrors 15, 17 and 19. Here, the exit pupil plane of the illumination optical unit 3 corresponds exactly to the entrance pupil plane 57 of the projection optical unit 5. Consequently, the second optical element 11 lies in a plane that is optically conjugate with respect to the entrance pupil plane 57 of the projection optical unit 5. For this reason, the intensity distribution of the radiation on the second optical element 11 is in a simple relationship with the angle-dependent intensity distribution of the radiation in the region of the object field 21. In this case, the entrance pupil plane of the projection optical unit 5 is defined as the plane perpendicular to the optical axis 39 in which the chief ray 59 intersects the optical axis 39 at the midpoint of the object field 21.

The task of the second facet elements 13 and of the downstream optical unit including the mirrors 15, 17 and 19 is to image the first facet elements 9 in a superimposing fashion onto the object field 21. In this case, superimposing imaging is understood to mean that images of the first reflective facet elements 9 are created in the object plane and at least partly overlap there. For this purpose, the second reflective facet elements 13 have a reflective optical surface with a normal vector whose direction fixes the orientation of the reflective optical surface in space. For each second facet element 13, the direction of the normal vector is chosen in such a way that the first facet element 9 associated therewith is imaged onto the object field 21 in the object plane 23. Since the first facet elements 9 are imaged onto the object field 21, the form of the illuminated object field 21 corresponds to the outer form of the first facet elements 9. The outer form of the first facet elements 9 is therefore usually chosen to be arced in such a manner that the long boundary lines of the illuminated object field 21 run substantially in a circular-arc shaped fashion about the optical axis 39 of the projection optical unit 5.

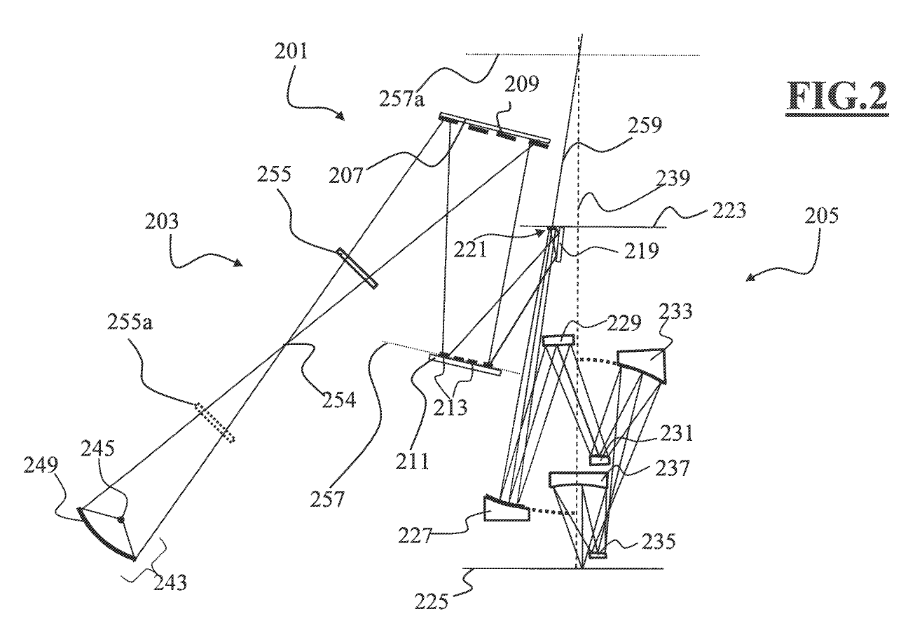

FIG. 2 shows a further embodiment of the illumination optical unit according to the disclosure in a micro lithography projection exposure apparatus. Here, the projection exposure apparatus 201 includes the illumination optical unit 203 and the projection optical unit 205. In contrast to the projection optical unit 5 illustrated in FIG. 1a, the projection optical unit 205 according to FIG. 2 has a negative vertex focal length of the entrance pupil. That is to say that the entrance pupil plane 257 of the projection optical unit 205 is arranged in the light path upstream of the object field 221. If the chief ray 259 is extended further, without taking account of the reflection at the structure-bearing mask at the location of the object field 221, then the chief ray intersects the optical axis 239 in the plane 257a. If account is taken of the reflection at the structure-bearing mask at the location of the object field 221 and at the deflection mirror 219, then the plane 257a coincides with the entrance pupil plane 257. In the case of such projection optical units having a negative vertex focal length of the entrance pupil, the chief rays at different object field points at the location of the object field 221 have a divergent ray path in the light direction. Projection optical units of this type are known from US 2009/0079952A1. A further difference with respect to the illumination optical unit according to FIG. 1a lies in the fact that the source plasma 245 is firstly imaged onto an intermediate focus 254 with the aid of the collector mirror 249. The intermediate focus 254 is then imaged onto the second reflective facet elements 213 of the second optical element 211 with the aid of the first reflective facet elements 209 of the first faceted optical element 207. In the illustrated embodiment, the filter element 255 is arranged in the light path between the intermediate focus 254 and the first reflective optical element 207 of the illumination optical unit 203. Alternatively, the filter element 255 can also be arranged in the light path between the light-source unit 243 and the intermediate focus 254. The corresponding positioning is illustrated by dotted lines in FIG. 2 and provided with reference sign 255a. Since it is preferable to suppress the radiation with the second wavelength as early as possible in the light path with the aid of the filter element, these are the two preferred positioning variants for the filter element 255.

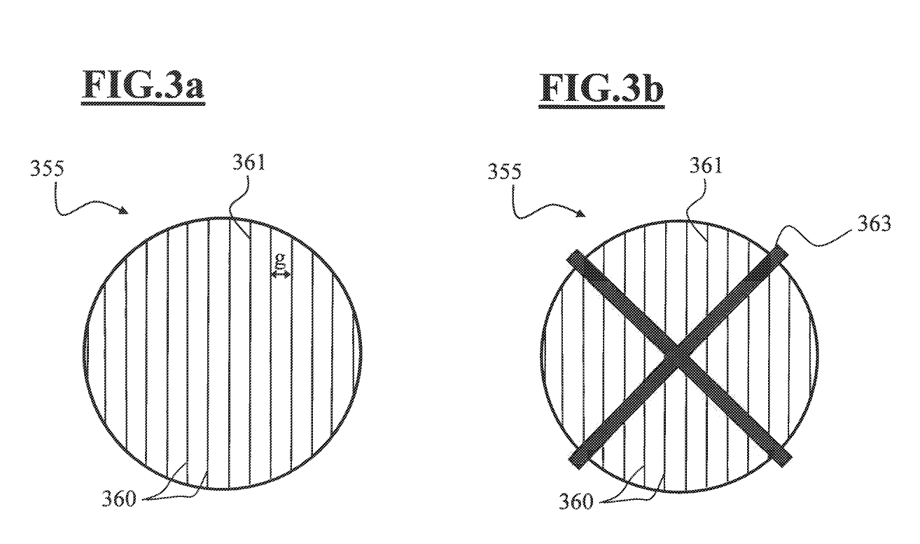

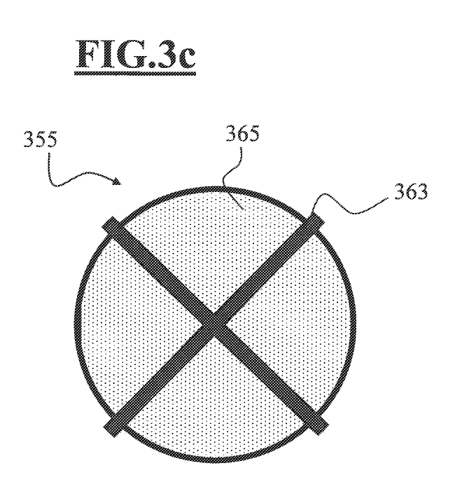

FIG. 3a illustrates a first embodiment of the filter element 355 according to the disclosure. Here, the filter element 355 is a periodic grating 360 with a grating period g. The grating period g refers to the distance between two adjacent grating struts 361. The grating period g has been selected in such a way that radiation with the second wavelength is absorbed. Here, the grating is a self-supporting grating made of a conductive material. In the illustrated case of a one-dimensional grating, only the radiation with the second wavelength that has a polarization direction parallel to the grating struts is absorbed. Hence such a grating is sufficient to the extent that the radiation with the second wavelength is polarized. Otherwise use is made of crossed gratings or a plurality of one-dimensional gratings for suppressing the radiation with the second wavelength. However, in addition to the wanted action on the radiation with the second wavelength, the filter element also has an effect on the radiation with the first wavelength. Since the radiation with the first wavelength is typically significantly shorter than the radiation with the second wavelength, the grating struts 361 have an obscuring action on the radiation with the first wavelength. If the first wavelength lies in the range of 5-15 nm and the second wavelength lies in the infrared range of 0.78 μm-1000 μm, the effects of the grating 360 on the radiation with the first wavelength can be calculated with the aid of geometric optics. This is due to the fact that the first wavelength is significantly shorter than the grating period matched to the second wavelength. The grating 360 accordingly also acts as an obscuring component on the radiation with the first wavelength. Hence, during the operation of the illumination optical unit, there are regions of reduced intensity (shadows) of radiation with the first wavelength on the first optical element, arranged downstream of the filter element 355 in the light direction, of the illumination optical unit as a result of the obscuring action of the grating 360.

FIG. 3b illustrates a developed embodiment of the grating 360. In addition to the grating struts 361 with the grating period g matched to the second wavelength, the grating has additional holding bodies 363. These holding bodies 363 serve to strengthen the mechanical stability of the filter element 355. Thus, in this case the grating struts are not self-supporting but are connected to the holding bodies 363. During the operation of the illumination optical unit, the holding bodies 363 likewise lead to regions of reduced intensity of radiation with the first wavelength on a first optical element arranged downstream of the filter element in the light direction. The holding bodies 363 therefore likewise form a component with an obscuring action.

FIG. 3c shows a further embodiment of the filter element according to the disclosure. In this embodiment, the spectral filter effect is achieved by a film 365, which absorbs a proportion of 90% of the radiation with the second wavelength and transmits a proportion of at least 70% of the radiation with the first wavelength. By way of example, a zirconium film with a thickness of 200 μm can be used as a film. In order to strengthen the mechanical stability of the filter element, holding bodies 363, which stabilize the thin film, are also provided in the embodiment according to FIG. 3c. Since the holding bodies are not transparent to the radiation with the first wavelength, these holding bodies 363 lead to regions of reduced intensity of radiation with the first wavelength on a first optical element arranged downstream of the filter element in the light direction.

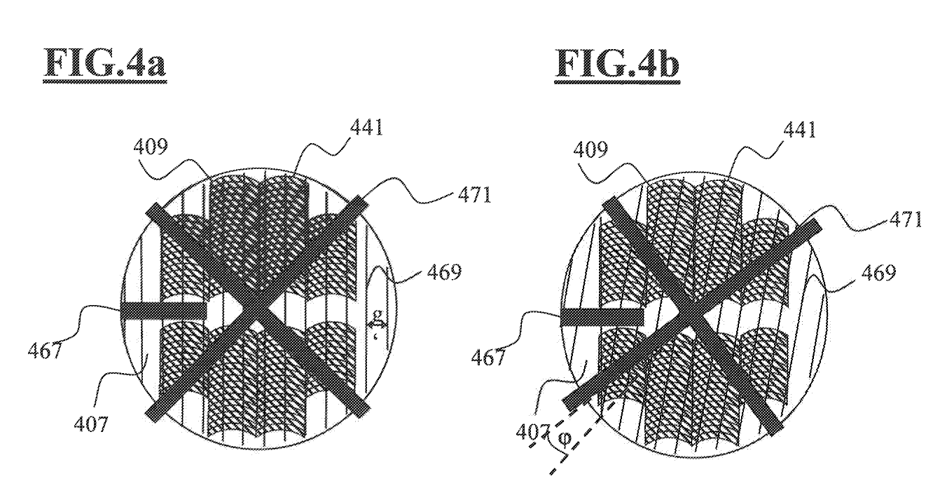

FIG. 4a shows a plan view of the first optical element 407 with first reflective facet elements 409. Furthermore, a number of regions of reduced intensity for radiation with the first wavelength are illustrated. The region 467 emerges as a result of components within the light-source unit with an obscuring action. By way of example, this is the droplet generator 49 illustrated in FIG. 1a. However, the first reflective facet elements 409 are arranged in such a way that the optical surfaces thereof do not fall into the region of reduced intensity 467. As a result, this region of reduced intensity has no effect on the quality of the illumination in the image plane since each point in the optical used surface 441 of the first optical element 407 lies outside of the region of reduced intensity 467. However, this does not apply to the regions of reduced intensity 469 and 471. These two regions emerge as a result of using a filter element in the embodiment according to FIG. 3b. The grating struts 361 illustrated in FIG. 3b lead to the regions of reduced intensity 469 and the holding bodies 363 illustrated in FIG. 3b lead to the regions of reduced intensity 471. The regions 469 have a grating structure with an imaged grating constant g′. Depending on the exact position, this imaged grating constant g′ emerges from the grating constant g with the aid of the corresponding imaging scale. As a result of the small distances between these regions, it proves impossible to arrange the first reflective facet elements in such a manner that the optical used surface of the first optical element 407 lies outside of the regions 469 and 471. Hence there are variations in the intensity of radiation with the first wavelength on every first reflective facet element 409 as a result of the filter element. Since the first reflective facet elements 409 are imaged into the object field with the aid of the subsequent optical unit, as explained in conjunction with FIG. 1a, there are also intensity variations of the radiation with the first wavelength in the object field as a result of the utilized filter element. In order to reduce the effects of these intensity variations on the lithographic process, the filter element is embodied in such a manner that it can assume a plurality of positions which lead to different regions of reduced intensity of radiation with the first wavelength on the first optical element 407. Thus, FIG. 4b shows a plan view of the first optical element 407 with the regions of reduced intensity 467, 469 and 471 after the filter element was shifted from a first position into a second position by virtue of being rotated through an angle φ about a central axis. Here the central axis is perpendicular to the surface of the filter element. The regions of reduced intensity 469 and 471 are also rotated through the angle φ compared to the illustration in FIG. 4a as a result of the rotation about the central axis through the angle φ. Hence, for every point on the optical used surface of the first optical element 409 there is at least one rotational angle φ, i.e. one position of the filter element, such that this point does not lie in a region of reduced intensity. As a result, rotating the filter element about the central axis with a sufficient rotational speed can render it possible that the intensity variations on the first optical element, and hence also in the object field, averaged over the exposure time, are significantly smaller than in the case of a static arrangement of the filter element. Alternatively, it is also possible to carry out a rotational movement in one direction through an angle followed by a rotational movement in the opposite rotational direction. From a mechanical point of view, this makes it easier to implement the active cooling via a coolant.

A typical exposure time during a lithographic process takes approximately t=10 ms. There is good smearing of the intensity variations on the first optical element if the structure of the regions 469 is displaced by an offset V which is ten times the imaged grating constant g′. In the case of a rotation, the offset V increases proportionally with the distance from the center of rotation:

V=β·r·t

where β denotes the angular speed of the rotation and r denotes the distance from the center of rotation. The regions 469 at the location of those first facet elements which lie closest to the center of rotation and hence assume the smallest value of r therefore experience the smallest offset V. In the case of typical designs of the first optical element, this spacing is r=30 mm. A typical imaged grating constant is approximately g′=15.9 μm.

$$g = \frac{10.6 μm}{2}$$

This emerges from a grating constant of multiplied by an imaging scale of 3.

$$V = β rt = β$$

$$30 mm 10 ms = 10$$

$$15.9 μm = 10 {g}^{′}$$

$$β = 0.57 \cdot \frac{rad}{s}$$

This corresponds to approximately 1 revolution in 11 s. In the case of an imaged grating constant of g′=3 mm, as is realistic for e.g. holding struts, approximately 16 revolutions per second emerge.

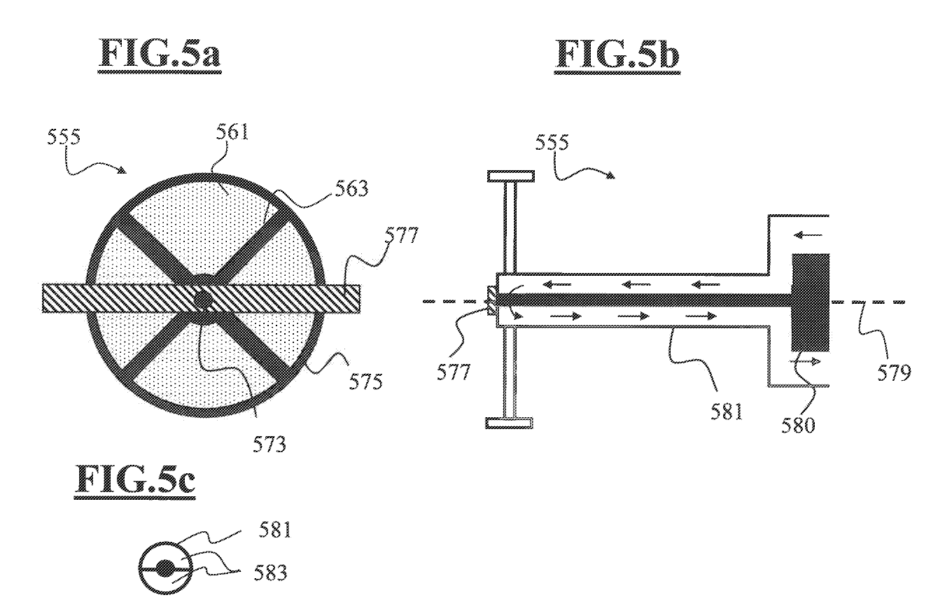

FIGS. 5a, 5b and 5c show various views of a preferred mechanical embodiment of the filter element. FIG. 5a shows a plan view of the filter element 555 in the light direction. In this case, the central axis intersects the filter element at the intersection point 573. In this embodiment, the central axis is arranged perpendicularly to the filter element and extends substantially in the direction of a mean light direction at the location of the filter element. The filter element includes various holding bodies 563, which extend radially with respect to the central axis. In addition to mechanical stabilization, the holding bodies are furthermore thermal conductors for cooling the filter element. To this end, the holding bodies are, for example, made of suitable material with high thermal conduction or else hollow struts which are filled with a liquid for heat transport. The filter element furthermore includes an outer ring 575, which likewise serves for mechanical stabilization of the filter element and for dissipating the taken-up heat. The filter element 555 is connected to a central holding device 577. FIG. 5b illustrates a section through the same filter element 555. Here, the sectional plane was placed in such a way that it contains the central axis 579. The filter element is connected to a shaft 581 for rotating the filter element at the location of the intersection point 573. The shaft is moreover connected to a drive unit 580. Here the shaft 581 extends along the central axis 579. Here the shaft 581 is a hollow body, through which a coolant can be conducted for cooling the filter element. The section shown in FIG. 5c, perpendicular to the central axis through the shaft, shows that the shaft includes two chambers 583 such that a coolant can be conducted to the filter element through one chamber and the coolant can be conducted away from the filter element through the other chamber. To this end, the two chambers are interconnected in the region of the intersection point 573 (shown in FIG. 5b).

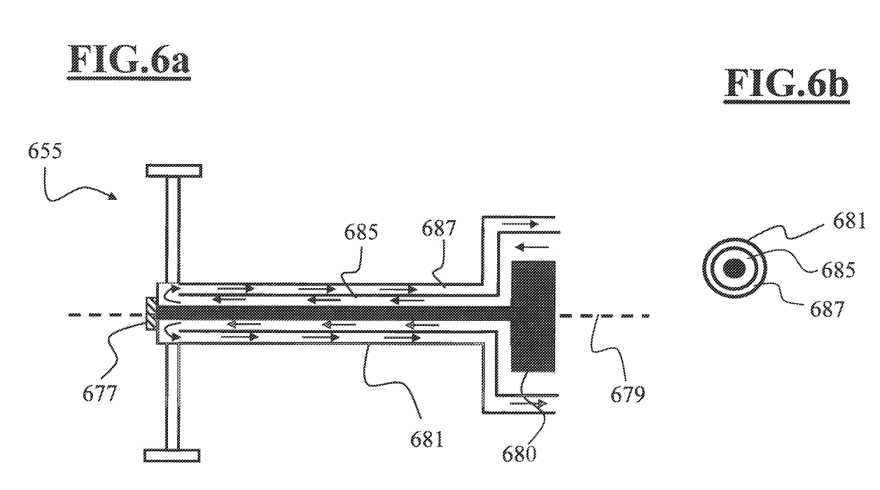

FIG. 6a shows a section through the same filter element 655 in an alternative embodiment. Here, the sectional plane was placed in such a way that it contains the central axis 679. In contrast to the embodiment according to FIG. 5b, the shaft 681 in this case includes an inner hollow cylinder 685 and an outer hollow cylinder 687. A coolant is conducted through the shaft through these two hollow cylinders in order to cool the shaft and hence also the filter element. FIG. 6b shows a section which extends through the shaft perpendicular to the central axis.

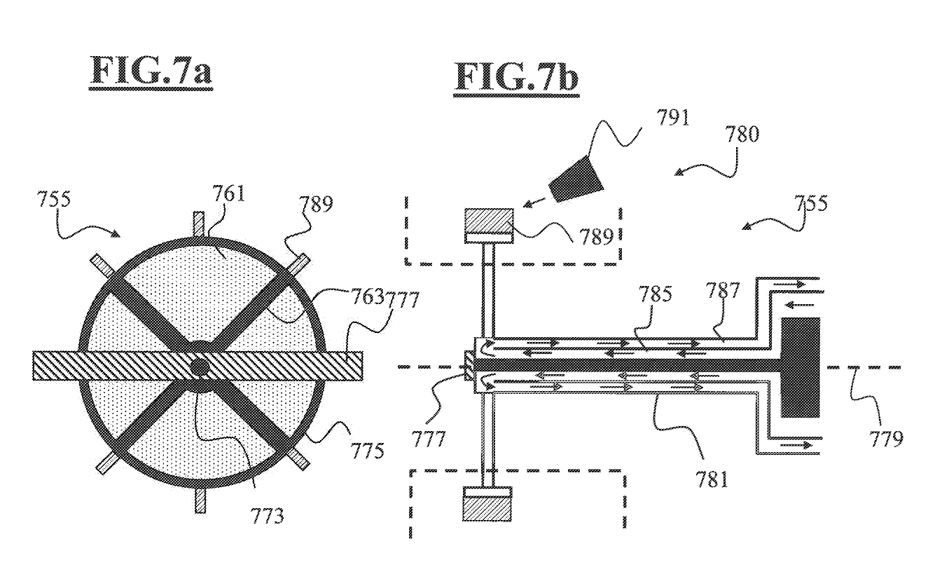

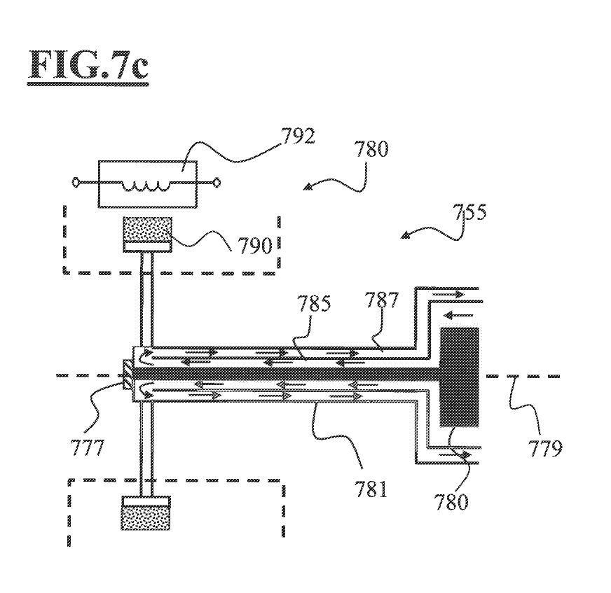

FIGS. 7a and 7b show various views of a further embodiment of the filter element according to the disclosure. FIG. 7a shows a plan view of the filter element 755 in the light direction. In contrast to the embodiment illustrated in FIG. 5a, paddles 789 are arranged on the circumference of the filter element 755, i.e. on the outer ring 775. Together with the gas actuator 791 shown in FIG. 7b, these paddles 789 serve as drive unit for rotating the filter element about the central axis 779. The drive unit for rotating the filter element therefore engages on a circumference of the filter element. FIG. 7b illustrates a section through the filter element 755 according to FIG. 7a. Here the sectional plane was placed in such a way that it contains the central axis 779. FIG. 7b also shows the paddles 789 arranged on the circumference. Furthermore, a gas actuator 791 is shown which generates a gas flow directed at the paddles. This is how a torque is transmitted onto the filter element, and so the filter element rotates about the central axis 779. The paddles and the actuator are preferably arranged in a hermetically sealed chamber 793. The filter element 755, as also the whole illumination optical unit, is situated within a vacuum because the radiation in the 5 to 15 nm range would otherwise be absorbed by remaining gases. In order simultaneously to maintain the vacuum and ensure the functioning of the gas actuator, use is made of the hermetically sealed chamber 793.

In an illustration similar to FIG. 7b, FIG. 7c shows a further embodiment in which the drive unit for rotating the filter element engages on the circumference. Permanent magnets 790 are arranged on the outer ring 775 in this embodiment in place of the paddles 789. There is at least one electromagnet 792 adjacent to the outer ring. The electric motor 792 is operated with alternating polarity and so a drive force is transmitted to the filter element via the permanent magnets 790. Just like in the case of the pneumatic drive illustrated in FIG. 7b, this renders it possible to avoid vibrations being transmitted from a mechanical drive to the filter element. Furthermore, the filter element is not rigidly connected, and so it can vibrate freely and expand when heated. A further advantage of this is that constraining forces acting on the filter element are avoided or reduced.

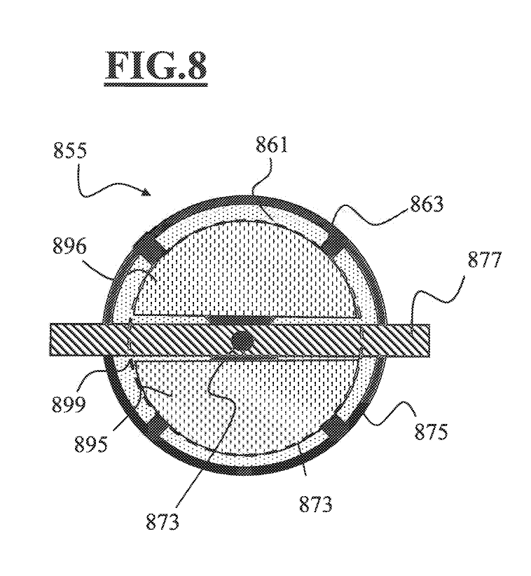

FIG. 8 shows the filter element according to FIG. 5a within a beam path. Two illuminated regions 895 and 896 are illustrated on the filter element 855. Such a subdivision into non-contiguous regions 895 and 896 emerges if the light-source unit has additional components with an obscuring action. Here, this can be, for example, the droplet generator 49 illustrated in FIG. 1a or else other mechanical components which block the radiation. In order, overall, to obscure as little radiation as possible, the holding device 877 is arranged in such a way that it is not illuminated. Hence no additional radiation is shadowed by the holding device 877. FIG. 8 moreover shows that the intersection point 873, at which the central axis intersects the filter element, lies within the convex envelope 899 of all regions 895 and 896 which are illuminated by the light-source unit. As a result, the intersection point 873 does not lie next to but rather in between the illuminated regions 895 and 896. As a result this achieves a particularly compact design if the filter element is rotated about the central axis.

What is claimed is:

1. An illumination optical unit configured to illuminate an object field with radiation having a first wavelength, the illumination optical unit comprising:
a filter element configured to suppress radiation having a second wavelength; and
an optical element downstream of the filter element along a path of the radiation having the first wavelength through the illumination optical unit,
wherein:
the filter element comprises a component configured to provide an obscuring action during use of the illumination unit;
as a result of the obscuring action, during use of the illumination optical unit there is at least one region of reduced intensity of the radiation having the first wavelength on the optical element;
the filter element is moveable between different positions;
during use of the illumination optical unit, different positions of the filter element lead to different regions of reduced intensity on the optical element;
for each point on an optical used surface of the optical element, there is at least one position of the filter element such that the point on the optical used surface of the optical element does not lie in a region of reduced intensity.

2. The illumination optical unit of claim 1, wherein the filter element comprises a periodic grating comprising a conductive material, and the grating period is selected in such a way that radiation with the second wavelength is absorbed.

3. The illumination optical unit of claim 2, wherein the period grating is the component of the filter element which provides an obscuring action during use of the illumination unit.

4. The illumination optical unit of claim 1, wherein the filter element comprises a film having a thickness of less than 500 nm, and during use of the illumination optical unit the film absorbs at least 90% of the radiation having the second wavelength and transmits at least 70% of the radiation having the first wavelength.

5. The illumination optical unit of claim 1, wherein the component of the filter element comprises holding bodies configured to strengthen a mechanical stability of the filter element.

6. The illumination optical unit of claim 5, wherein the holding bodies comprise thermal conductors configured to cool the filter element.

7. The illumination optical unit of claim 6, wherein the holding bodies comprise hollow struts containing a liquid for heat transport.

8. The illumination optical unit of claim 1, wherein the filter element is rotatable about a central axis of the filter element.

9. The illumination optical unit of claim 8, further comprising a shaft extending along the central axis of the filter element and connected to the filter element, wherein the shaft is configured to rotate the filter element about the central axis of the filter element.

10. The illumination optical unit of claim 8, further comprising a drive unit configured to rotate the filter element about the central axis of the filter element, wherein the drive unit engages a circumference of the filter element.

11. The illumination optical unit of claim 10, further comprising paddles on the circumference of the filter element, wherein the drive unit comprises a gas actuator configured to produce a gas flow directed at the paddles.

12. An illumination system, comprising:
a light source configured to produce radiation having a first wavelength and radiation having a second wavelength; and
an illumination optical unit according to claim 1.

13. An apparatus, comprising:
an illumination system, comprising:
a light source configured to produce radiation having a first wavelength and radiation having a second wavelength; and
an illumination optical unit according to claim 1; and
a projection objective,
wherein the apparatus is a microlithography projection exposure apparatus.

14. A method, comprising:
providing a microlithography projection exposure apparatus, comprising:
an illumination optical system comprising an illumination optical unit according to claim 1; and
a projection objective; and
moving the filter element from a first position to a second within a time period which is less than a time period during which a point on the structure-bearing mask is moved through the object field.

15. An illumination system, comprising:
a light source configured to produce radiation having a first wavelength and radiation having a second wavelength; and
an illumination optical unit configured to illuminate an object field with the radiation having the first wavelength, the illumination optical unit comprising:
a filter element configured to suppress the radiation having the second wavelength; and
an optical element downstream of the filter element along a path of the radiation having the first wavelength through the illumination optical unit,
wherein:
the filter element comprises a component configured to provide an obscuring action during use of the illumination unit;
as a result of the obscuring action, during use of the illumination system there is at least one region of reduced intensity of the radiation having the first wavelength on the optical element;
the filter element is moveable between different positions;
during use of the illumination system, different positions of the filter element lead to different regions of reduced intensity on the optical element;
for each point on an optical used surface of the optical element, there is at least one position of the filter element such that the point on the optical used surface of the optical element does not lie in a region of reduced intensity;
the filter element is rotatable about a central axis of the filter element which intersects the filter element at an intersection point; and
the intersection point lies within a convex envelope of all regions on the filter element which are illuminated by the light-source unit with radiation having the first and the second wavelengths during use of the illumination system.

16. The illumination optical system of claim 15, further comprising a shaft extending along the central axis of the filter element and connected to the filter element, wherein the shaft is configured to rotate the filter element about the central axis of the filter element.

17. An apparatus, comprising:
an illumination system according to claim 15; and
a projection objective,
wherein the apparatus is a microlithography projection exposure apparatus.

18. A method, comprising:
providing a microlithography projection exposure apparatus, comprising:
an illumination optical system according to claim 15; and
a projection objective; and
moving the filter element from a first position to a second within a time period which is less than a time period during which a point on the structure-bearing mask is moved through the object field.

19. The method of claim 18, further comprising rotating the filter element about its central axis with a speed of more than 5 revolutions per second.

20. A method, comprising:
providing a microlithography projection exposure apparatus, comprising:
an illumination optical system according to claim 15; and
a projection objective; and
rotating the filter element about its central axis with a speed of more than 5 revolutions per second.
